(19) United States
(12) Patent Application Publication
(10) Pub. No.: US 2024/0192273 A1
(43) Pub. Date: Jun. 13, 2024

(54) Method for Detecting a Stuck AC Switch in a Converter

(71) Applicant: ABB E-mobility B.V., Delft (NL)

(72) Inventors: Michele Motta, Nocera Terinese (IT); Gianluca Rondine, Nardò (IT); Simone Paolini, Terranuova Bracciolini (IT); Giulio Betti, Monte San Savino (IT); Martino Romano, Terranuova B. NI. (IT); Marco Lega, Bucine (IT)

(73) Assignee: ABB E-mobility B.V., Delft (NL)

(21) Appl. No.: 18/531,848

(22) Filed: Dec. 7, 2023

(30) Foreign Application Priority Data
Dec. 9, 2022 (EP) 22212455.4

(51) Int. Cl. G01R 31/327; H02M 7/79

(52) U.S. Cl. CPC G01R 31/327; H02M 7/79

(57) ABSTRACT

A converter arrangement connects to a DC source or load and to a plurality of AC terminals. Each converter arrangement includes a DC part with two capacitors arranged in parallel to the DC source or DC load and a neutral DC point between them. At least one AC leg is connected to a neutral AC point via an AC leg capacitor. A pre-charge unit is arranged at each leg of the AC terminal. The method includes opening a decoupling switch and all second AC switches; loading the pre-charge unit; sequentially closing each second AC switch; measuring at each closing step a voltage between each AC leg of the second converter arrangement; and determining the stuck AC switch of the second converter arrangement based on the measured voltage.

### CROSS-REFERENCE TO RELATED APPLICATIONS

The instant application claims priority to European Patent Application No. 22212455.4, filed Dec. 9, 2022, which is incorporated herein in its entirety by reference.

### FIELD OF THE DISCLOSURE

The present disclosure relates to converters such as DC/AC or AC/DC converters, and more particularly to a method for detecting a stuck AC switch in a converter.

### BACKGROUND OF THE INVENTION

To operate converters safely, checking a healthy status of the AC switches may be useful or necessary, before turning on the converter. For a converter with only a few lines and, thus, only a few AC switches, it may be possible to switch on and off each single AC switch for testing whether it functions. However, even for a small number of AC switches this may impose considerable effort for the service personnel; and for a high number of AC switches—e.g., in converter systems, where many power converters are arranged in parallel—the effort may become prohibitive. However, using multiple power converters connected in parallel may be useful for building modular systems of high flexibility and/or for redundancy concepts.

### BRIEF SUMMARY OF THE INVENTION

The present disclosure describes an improved method for detecting a stuck AC switch, particularly in a converter that comprises a plurality of converter arrangements arranged in parallel.

One aspect relates to a method for detecting a stuck AC switch in a converter, the converter comprising a plurality of converter arrangements arranged in parallel. The converter arrangements are configured for connecting to a DC source or DC load, and configured for connecting to a plurality of AC terminals. Each converter arrangement comprises a DC part, comprising two capacitors, arranged in parallel to the DC source or DC load, and arranged in series to each other, having a neutral DC point between said capacitors; a converter unit, connected to the DC source or DC load and to an AC part, the AC part comprising at least one AC leg, each AC leg connected to a neutral AC point via an AC leg capacitor, and each AC leg connected to a respective leg of the AC terminal via an AC switch; a pre-charge unit, arranged at each leg of the AC terminal; and a decoupling switch, arranged between the neutral DC point and the neutral AC point. The method comprises the steps of. Opening the second decoupling switch and all second AC switches of the second converter arrangement; loading the pre-charge unit; sequentially closing each second AC switch of the second converter arrangement; measuring, at each closing step, a voltage between each AC leg of the second converter arrangement; and determining the stuck AC switch of the second converter arrangement based on the measured voltage.

### BRIEF DESCRIPTION OF THE SEVERAL VIEWS OF THE DRAWING(S)

FIG. 1 is a schematic diagram of a converter according to an embodiment of the present disclosure.

FIGS. 2a and 2b are schematic diagrams of the converter of FIG. 1 with current flows according to an embodiment of the present disclosure.

FIG. 3 is a schematic diagram of the converter of FIG. 1 having other current flows according to an embodiment of the present disclosure.

FIG. 4 is a flowchart for a method in accordance with the disclosure.

### DETAILED DESCRIPTION OF THE INVENTION

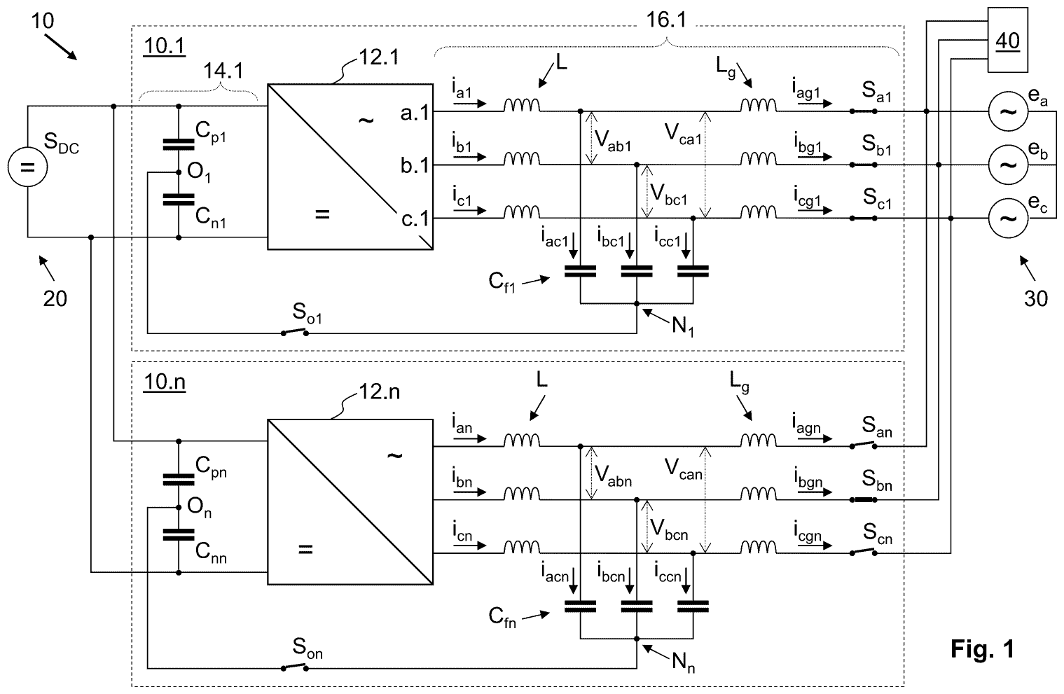

FIG. 1 shows schematically a converter 10 according to an embodiment. The converter 10 comprises a plurality of converter arrangements 10.1, 10.n, arranged in parallel. The converter arrangements 10.1, 10.n are connected to a DC unit 20. If the converter 10 is run as a DC/AC converter (as shown), the DC unit 20 functions as a DC source SDC. If the converter 10 is run as an AC/DC converter (not shown), the DC unit 20 functions as a DC load. The converter arrangements 10.1, 10.n are further connected to a plurality of AC terminals 30, comprising the elements eₐ, e_{b}, and e_{c}, for each AC leg a, b, and c, respectively. Each converter arrangement 10.1, 10.n comprises a DC part 14.1 and 14.n, respectively (for a better overview, only the reference sign for DC part 14.1 of converter arrangement 10.1 is depicted). The DC part 14.1 comprises two capacitors Cₚ₁, Cₙ₁, arranged in parallel to the DC unit 20. Between the capacitors Cₚ₁ and Cₙ₁, a neutral DC point O₁ is given. The DC part 14.n comprises, analogously, two capacitors Cₚ₁ and Cₙ₁, and a neutral DC point Oₙ. Furthermore, a converter unit 12.1, 12.n, connected to the DC unit 20 and to the AC part 16.1, 16.n is shown as part of converter arrangements 10.1 and 10.n, respectively.

Each converter arrangement 10.1, 10.n further comprises an AC part 16.1 and 16.n, respectively (for a better overview, only the reference sign for AC part 16.1 of converter arrangement 10.1 is depicted). The AC part 16.1, 16.n comprises, in this embodiment, three AC legs a.1, b.1, c.1 (of 16.1) and a.n, b.n, c.n (of 16.n). Each one of the AC legs is connected to a neutral AC point N₁, Nₙ via an AC leg capacitor C_{fa1}, C_{fb1}, C_{fc1}, C_{fan}, C_{fbn}, C_{fcn}. Also, each one of the AC legs is connected to a respective leg of the AC terminal 30 via AC switches Sₐ₁, S_{b1}, S_{c1} (of converter arrangement 10.1) and AC switches Sₐₙ, S_{bn}, S_{cn} (of converter arrangement 10.n). The switch S_{bn} is depicted as being stuck. Each converter arrangement 10.1, 10.n additionally comprises a decoupling switch Sₒ₁, Sₒₙ, arranged between the neutral DC point O₁, Oₙ and the neutral AC point N₁, Nₙ.

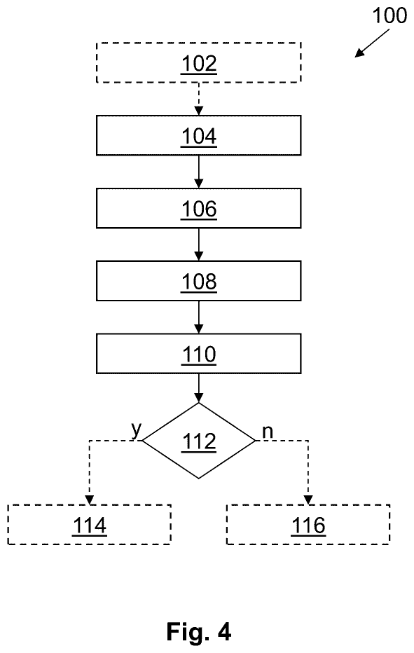

FIG. 4 shows a flow diagram according to an embodiment. In an optional step 102, a pre-charge unit 40 (see, e.g., FIG. 1) is loaded. This step may be unnecessary, if AC elements eₐ, e_{b}, and e_{c} are an AC source. In a step 104, the second decoupling switch Sₒₙ and all second AC switches Sₐₙ, S_{bn}, S_{cn} of the second converter arrangement 10.n are opened. In a step 106, all first AC switches Sₐ₁, S_{b1}, S_{c1} of the first converter arrangement 10.1 are closed. In a step 108, each second AC switch Sₐₙ, S_{bn}, S_{cn} of the second converter arrangement 10.n is closed in a sequential way, i.e., for three AC switches Sₐₙ, S_{bn}, S_{cn}, in sub-steps 108(i), 108(ii), and 108(iii). In a step 110 (which may be parallel to step 108), at each closing step 108(i) to 108(iii), a voltage V_{abn}, V_{bcn}, V_{can} between each AC leg a.n, b.n, c.n of the second converter arrangement 10.n is measured. In a step 112, the stuck AC switch S_{bn} of the second converter arrangement 10.n is determined, based on the measured voltage V_{abn}, V_{bcn}, V_{can}. If at least one of the AC switches Sₐ₁, S_{b1}, S_{c1}, Sₐₙ, S_{bn}, S_{cn} of the related converter arrangement 10.1, 10.n is found stuck, in an optional step 114, the decoupling switches Sₒ₁, Sₒₙ are kept open. If all AC switches operate well, and/or during normal operation, the decoupling switches Sₒ₁, Sₒₙ are closed, in an optional step 116. The following table provides an additional survey over the steps, where switch S_{bn} is stuck:

| Step | Sₐₙ | S_{bn} | S_{cn} | Sₒₙ | V_{abn} | V_{bcn} | V_{can} |
|---|---|---|---|---|---|---|---|
| open all Sₙ | 0 | 0 | 0 | 0 | 0 | 0 | 0 |
| 108(i) & 110 | 1 | 0 | 0 | 0 | eₐ + e_{b} | 0 | 0 |
| 108(ii) & 110 | 0 | 1 | 0 | 0 | 0 | 0 | 0 |
| 108(iii) & 110 | 0 | 0 | 1 | 0 | 0 | e_{b} + e_{c} | 0 |
| 112 & 114 | 0 | 0 | 0 | 0 | 0 | 0 | 0 |

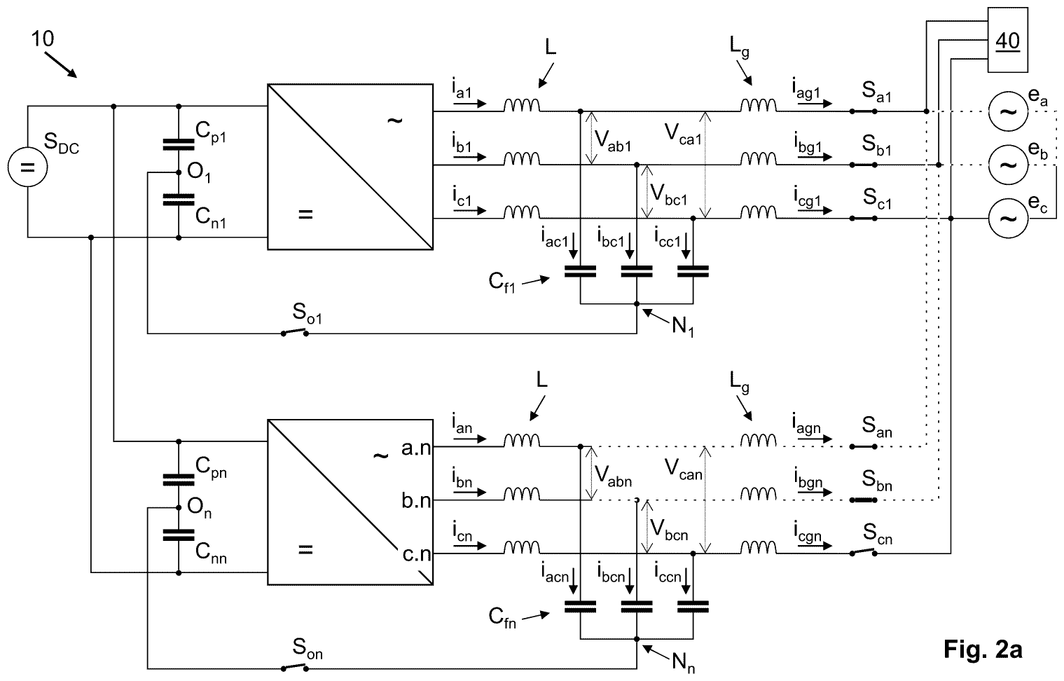

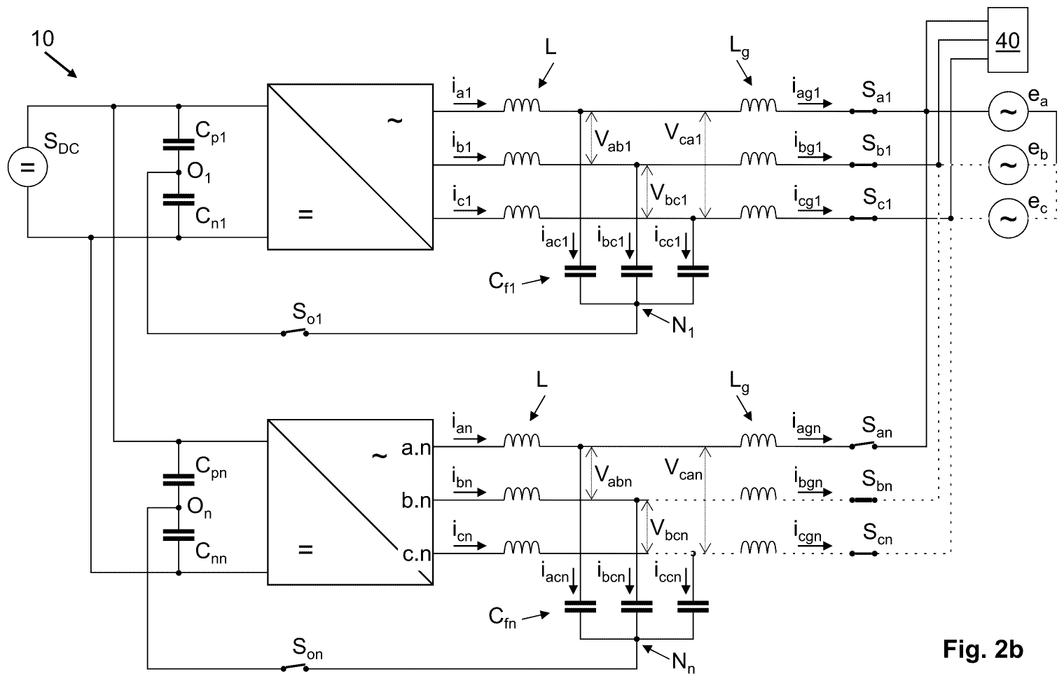

FIG. 2a and FIG. 2b show schematically the converter 10 of FIG. 1 with current flows according to an embodiment. The switch S_{bn} is depicted as being stuck. In FIG. 2a, currents of step 108(i) are shown. In step 108(i), AC switch Sₐₙ is closed (according to the method) and AC switch S_{bn} is stuck (because it is faulty). Thus, between legs a.n and b.n of the second converter arrangement 10.n a voltage V_{abn}=ea+eb can be measured. In embodiments where ea, eb, and ec are loads, there may be still a voltage from the grid and, accordingly, the measured voltage is the grid. In cases when the grid is off, a voltage may come from the pre-charge unit. The measuring point for the voltages V_{abn}, V_{bcn}, V_{can} must, of course, be “behind” the AC switches Sₐₙ, S_{bn}, S_{cn}, seen from sources ea, eb, and ec or from the pre-charge unit 40, respectively.

In FIG. 2b, currents of step 108(iii) are shown. In step 108(iii), AC switch S_{cn} is closed (according to the method) and AC switch S_{bn} is stuck (because it is faulty). Thus, a voltage V_{bcn}=e_{b}+e_{c} can be measured between legs b.n and c.n of the second converter arrangement 10.n. In embodiments, ea, eb, and ec may be the voltages on an electrical grid, independently if the grid is used as load or as source.

Note that in step 108(ii) no voltage can be measured, because AC switch S_{bn} is closed (stuck) and AC switches Sₐₙ and Se are open, because they work properly.

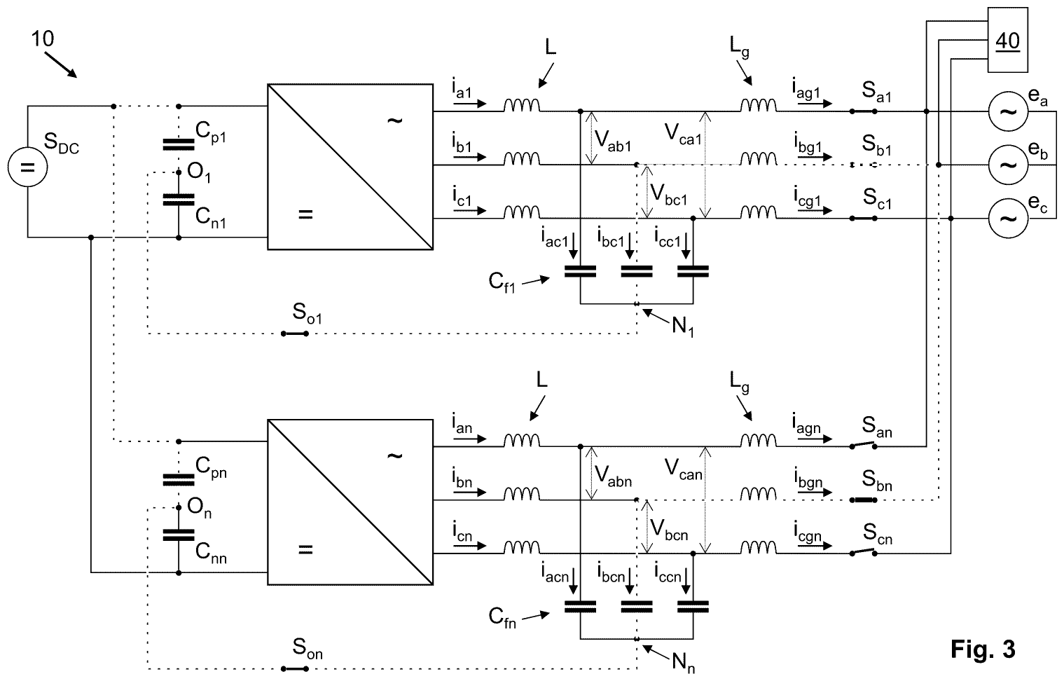

FIG. 3 shows schematically the converter 10 of FIG. 1 with other current flows according to an embodiment. The current flows depicted here can be measured when decoupling switches So1 and Son are closed, or if these switches So1 and Son are not available, as can be found in legacy converters. Without the decoupling switches So1 and Son (depicted here as closed decoupling switches So1 and Son) in the related converter arrangement 10.1, 10.n, the circulation path for a homopolar current between the converters cannot be interrupted. When a plurality of converter arrangements 10.1, 10.n are arranged in parallel, a path for the homopolar current is created. The effects of the homopolar current may comprise a deteriorated power quality and/or a worse condition that degrades the performance of the overall system. As shown in FIG. 3, the faulty (stuck) AC switch S_{bn} leads to a current through the AC switch S_{b1} and S_{bn} and, further—because decoupling switches So1 and Sₒₙ are not available—to currents between the neutral AC points N1, Nn and the neutral DC point O1, On, in the respective converter arrangement 10.1 and 10.n and, again further, through capacitors Cp1 and Cₚₙ. An additional or alternative way may be via capacitors Cₙ₁ and Cₙₘ (not shown). It can clearly be seen that, although converter arrangement 10.n may have been excluded from operation, the performance of any other converter arrangement in the system may be affected seriously.

A stuck AC switch is a switch that is continuously closed, i.e., continuously conductive. This may have been caused, at mechanical switches, by “gluing” the contacts of the switch, e.g., due to high current. This may have been caused, at electric switches, by a thermal damage. Other causes may apply as well. The AC switch may be arranged in a way to switch on and off a line of the converter arrangement that leads to the AC terminal. The converter comprises a plurality of converter arrangements, arranged in parallel. The converter may be designed as a DC/AC converter or as an AC/DC converter and/or as a bidirectional converter. In the following, some explanations may, for simplicity reasons, be mainly related to a DC/AC converter type (or, to a DC/AC converter arrangement, or to a DC/AC converter unit); however, these explanations may, analogously, also be applied to the other converter types.

Each converter arrangement is configured for connecting, on its DC side, to a DC source or DC load, and each converter arrangement is configured for connecting, on its AC side, to a plurality of AC terminals. The number of AC terminals of each converter arrangement may be dependent on the number of rails or legs the converter supports. For instance, for a converter that supports a three-phase power supply, each converter arrangement has three AC legs, each AC leg of the converter arrangement with a switch in the line leading to the converter's AC terminal. For the three-phase example, the converter's AC terminal may lead to loads eₐ, e_{b}, and e_{c} (or to sources, for the other converter types), for phases a, b, and c, respectively. For other numbers of AC rails, e.g., for one rail or AC leg, for two, three, four, five or more AC legs may have the respective number of AC switches in each converter arrangement. The loads eₐ, e_{b}, and e_{c} (or sources) may be connected to an electric grid, for instance to an MV (medium voltage) grid or to a low voltage grid.

Each converter arrangement comprises a DC part. The DC part, comprises two capacitors, arranged in parallel to the DC source or DC load, and arranged in series to each other. Thus, a neutral DC point is located between these capacitors. Each converter arrangement further comprises a converter unit (DC/AC, AC/DC, and/or bidirectional), connected to the DC source or DC load and to an AC part. The AC part comprises at least one AC leg (or two to five or more AC legs), each AC leg connected to a neutral AC point via an AC leg capacitor, and each AC leg connected to a respective leg of the AC terminal via the AC switch. The AC leg capacitor may be part of an LCL filter. The neutral AC point may also be called “star center” of the AC part or of the AC LCL filter. Each converter arrangement further comprises a decoupling switch, arranged between the neutral DC point and the neutral AC point.

The method may be performed before starting the converter and/or one or more of the converter arrangements. The method may, additionally or as an alternative, be performed as a part of a service routine. For the method, the second decoupling switch and all second AC switches of the second converter arrangement are opened. Then all first AC switches of the first converter arrangement are. After this, each second AC switch of the second converter arrangement is closed sequentially. A closing sequence for an exemplary converter with three AC legs is given below. At each closing step, a voltage between each AC leg of the second converter arrangement is measured. Based on the voltage measured this way, the stuck AC switch of the second converter arrangement can be determined. For instance, if no voltage is measured in any step, all the second AC switches of the second converter arrangement work properly. In case a voltage is measured in at least one step, an AC switch can be recognized as being stuck. The voltage may come (when the converter is operated as an AC/DC converter) from the AC source on the AC terminals. In other embodiments, the voltage may, e.g., come from a pre-charge unit that has been loaded before this checking sequence. The pre-charge unit may be not necessary, if the AC part delivers power, particularly if it delivers power continuously, and/or if the DC bus is already charged (e.g., at photovoltaic inverters).

Thus, the method checks the AC switches for a safe operation of the converter with very low additional costs and/or additional size of the converter. The healthy status of the AC switches may this way be checked before turning on the converter. A stuck AC switch can be detected at low effort, particularly in a converter that comprises a plurality of converter arrangements arranged in parallel. Furthermore, this method allows to perform the healthy check also while other parallel connected converters are turned on. Moreover, the decoupling switch allows the interruption of the circulation path for the homopolar current between the converters. Without the decoupling switch, when there are multiple converters connected in parallel, a standard healthy check cannot be applied, because this would introduce a homopolar current that may trigger the overcurrent protections in the converter arrangements that are already working. This would degrade the performance and/or the reliability of the complete converter system.

In various embodiments, the method further comprising the step of: Before loading the pre-charge unit, closing all first AC switches of the first converter arrangement. The pre-charge unit may only be used if the DC bus is not charged by any other source (e.g., photovoltaic system) and before turning on the first converter. So, the switches of the first converter may be closed only once the first converter is ready to switch ON and if the DC bus voltage is charged.

In various embodiments, the method further comprising the step of: When opening the second decoupling switch of the second converter arrangement, opening decoupling switches of all converter arrangements. In detail, a proceeding may comprise following steps, e.g., in cases when all converters are off and if the converter operates as an AC/DC converter, i.e., if it takes energy from the AC grid: (1) Pre-charge the DC bus with the pre-charge unit. (2) First converter performs the algorithm as described above and/or below to look for stuck AC switches. (3) If there are not stuck AC switches, then converter 1 closes all the AC switches and starts to take power from the AC grid.

Once there is voltage on the DC bus, power from the pre-charge unit may be unnecessary. Furthermore, the other converters may perform the algorithm as described above and/or below to find stuck contactors in the grid.

The i-th decoupling switch may be closed once the i-th converter is started. Each converter may control its own decoupling switches. The decoupling switch may be open once the converter is shut down.

Generally, each converter may operate its own decoupling switch. During normal operation, the decoupling switch is open. It may be open when the converters check possible AC stuck switches. If there are not any stuck switches, the converter may close its own decoupling switch and may start to operate.

In various embodiments, the decoupling switches are kept open, if at least one of the AC switches of the related converter arrangement is found stuck. Generally, it is advantageous to switch off the decoupling switch when the converter is not operating and/or during the healthy check. When one of the converter arrangements has diagnosed a stuck switch. Then, although the affected converter arrangement would be excluded from the operations, the performance of any other converter arrangement would be the system is seriously affected, without the decoupling switch. With the decoupling switch the problematic converter can advantageously be isolated.

In various embodiments, the AC switch and/or the decoupling switch is a mechanical switch, a relay, an IGBT (Insulated-Gate Bipolar Transistor), and/or a MOSFET (metal-oxide-semiconductor field-effect transistor). The selection of the switch type may be influenced by the voltage and/or the power that needs to be switched. In some embodiments, it may make sense to use a switch with mechanical and/or visible feedback. For some types of converters, better feedback, e.g., for the service personnel, may thus be provided.

In some embodiments, the converter unit and/or the converter arrangement has one AC leg, two, three, four or five AC legs. Although embodiments with three AC legs may be quite common, there is no principal limit for the number of legs to implement in the converter. The method is basically suitable for a wide range of converter legs. In some embodiments, the converter unit is a T-type converter.

In various embodiments, the converter unit is designed as a DC/AC converter or as an AC/DC converter. In various embodiments, the converter unit is a bidirectional converter.

In some embodiments, the AC leg capacitor is part of an LCL filter. The LCL filter may comprise two inductors in series, between them the AC leg capacitor, which is connected to the neutral AC point. The LCL filter work as an improved low-pass filter, possibly additionally or as an alternative to a low-pass filter in the converter unit(s).

An aspect relates to a converter arrangement. The converter arrangement comprises a DC part, comprising two capacitors, arranged in parallel to the DC source or DC load, and arranged in series to each other, having a neutral DC point between said capacitors; a converter unit, connected to the DC source or DC load and to an AC part, the AC part comprising at least one AC leg, each AC leg connected to a neutral AC point via an AC leg capacitor, and each AC leg connected to a respective leg of the AC terminal via an AC switch; and a decoupling switch, arranged between the neutral DC point and the neutral AC point.

An aspect relates to a converter, comprising a plurality of converter arrangements, arranged in parallel and, optionally, a pre-charge unit as described above and/or below. The converter may be configured for voltages between 5 and 3000 V. The converter's voltage ranges and/or power ranges may depend on the voltage and/or power ranges the switches are specified for.

An aspect relates to a use of a converter arrangement and/or a converter for an MV (medium voltage) converter, UPS (uninterrupted power supply) systems, BESS (battery energy storage system), EV (electric vehicle) charging, a PV (photovoltaic) inverter, and/or further DC/AC converting systems. The method may presuppose a presence of a voltage on the AC side.

An aspect relates to a computer program product comprising instructions, which, when the program is executed by a control unit, cause the control unit to carry out the method as described above and/or below.

An aspect relates to a computer-readable storage medium where a computer program or a computer program product as described above is stored on.

It should be noted that two of more embodiments described above and/or below can be combined, as far as technically feasible.

For further clarification, the invention is described by means of embodiments shown in the figures. These embodiments are to be considered as examples only, but not as limiting.

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and “at least one” and similar referents in the context of describing the invention (especially in the context of the following claims) are to be construed to cover both the singular and the plural, unless otherwise indicated herein or clearly contradicted by context. The use of the term “at least one” followed by a list of one or more items (for example, “at least one of A and B”) is to be construed to mean one item selected from the listed items (A or B) or any combination of two or more of the listed items (A and B), unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

What is claimed is:

1. A method for detecting a stuck AC switch in a converter, the converter comprising:
a plurality of converter arrangements arranged in parallel and configured for connecting to a DC source or DC load and for connecting to a plurality of AC terminals, wherein each of the plurality of converter arrangement comprises:
a DC part comprising two capacitors arranged in parallel to the DC source or DC load and arranged in series to each other having a neutral DC point between said capacitors;
a converter unit connected to the DC source or DC load and to an AC part;
the AC part comprising at least one AC leg, each AC leg connected to a neutral AC point via an AC leg capacitor, and each AC leg connected to a respective leg of the AC terminal via an AC switch,
a pre-charge unit arranged at each leg of the AC terminal, and
a decoupling switch arranged between the neutral DC point and the neutral AC point,
the method comprising the steps of:
opening the second decoupling switch and all second AC switches of the second converter arrangement;
loading the pre-charge unit;
sequentially closing each second AC switch of the second converter arrangement;
measuring, at each closing step, a voltage between each AC leg of the second converter arrangement; and
determining the stuck AC switch of the second converter arrangement based on the measured voltage.

2. The method of claim 1, the method further comprising the step of, before loading the pre-charge unit, closing all first AC switches of the first converter arrangement.

3. The method of claim 2, further comprising the step of, when opening the second decoupling switch of the second converter arrangement, opening decoupling switches of all converter arrangements.

4. The method of claim 1, wherein the decoupling switches are kept open, when at least one of the AC switches of the related converter arrangement is found stuck, and/or wherein the decoupling switches are closed during normal operation of the converter.

5. The method of claim 1, wherein the AC switch and/or the decoupling switch is a mechanical switch, a relay, an IGBT, and/or a MOSFET.

6. The method of claim 1, wherein the converter unit and/or the converter arrangement has one AC leg, two, three, four or five AC legs, and/or the converter unit is a T-type converter.

7. The method of claim 1, wherein the converter unit is configured as a DC/AC converter or as an AC/DC converter.

8. The method of claim 1, wherein the converter unit is a bidirectional converter.

9. The method of claim 1, wherein the AC leg capacitor is part of an LCL filter.

10. A converter arrangement, comprising:
a DC part comprising two capacitors arranged in parallel to the DC source or DC load and arranged in series to each other, having a neutral DC point between said capacitors,
a converter unit connected to the DC source or DC load and to an AC part, the AC part comprising at least one AC leg, each AC leg connected to a neutral AC point via an AC leg capacitor, and each AC leg connected to a respective leg of the AC terminal via an AC switch, and
a decoupling switch arranged between the neutral DC point and the neutral AC point.

11. A converter comprising a plurality of converter arrangements according to claim 10, arranged in parallel, further comprising a pre-charge unit.
